(19) United States
(12) Patent Application Publication
(10) Pub. No.: US 2026/0226618 A1
(43) Pub. Date: Aug. 6, 2026

(54) SUBSTRATE PROCESSING APPARATUS WITH FLOW CONTROL RING, AND SUBSTRATE PROCESSING METHOD

(71) Applicant: ASM IP Holding B.V., Almere (NL)

(72) Inventor: Naoto Tsuji, Tokyo (JP)

(21) Appl. No.: 19/576,643

(22) Filed: Mar. 24, 2026

Related U.S. Application Data
(63) Continuation of application No. 17/670,030, filed on Feb. 11, 2022, now Pat. No. 12,637,766.
(60) Provisional application No. 63/150,082, filed on Feb. 16, 2021.

(51) Int. Cl. C23C 16/455; C23C 16/458; H10P 14/20; H10P 72/00

(52) U.S. Cl. CPC C23C 16/45536; C23C 16/45508; C23C 16/45565; C23C 16/4585; H10P 14/20; H10P 72/0421

(57) ABSTRACT

Examples of a substrate processing apparatus includes a chamber, a susceptor provided in the chamber, a shower head provided above the susceptor, and a flow control ring having a shape to surround the susceptor, the flow control ring having a first top surface and a second top surface that has an annular shape and is provided closer to an inner edge of the flow control ring than the first top surface at a higher level than the first top surface, the second top surface being a sloped surface whose height decreases toward the first top surface.

### CROSS-REFERENCE TO RELATED APPLICATIONS

This application is a continuation of, and claims priority to, U.S. patent application Ser. No. 17/670,030 filed Feb. 11, 2022 titled SUBSTRATE PROCESSING APPARATUS WITH FLOW CONTROL RING, AND SUBSTRATE PROCESSING METHOD; which claims priority to U.S. Provisional Patent Application Ser. No. 63/150,082, filed on Feb. 16, 2021, titled SUBSTRATE PROCESSING APPARATUS WITH FLOW CONTROL RING, AND SUBSTRATE PROCESSING METHOD, the disclosures of which are hereby incorporated by reference in their entirety.

### FIELD

Examples are described which relate to a substrate processing apparatus with a flow control ring.

### BACKGROUND

In the plasma enhanced atomic layer deposition (PEALD), for example, a flow control ring (FCR) is used. An FCR is a ring provided to surround a susceptor. Gas used for processing of the substrate on the susceptor is guided by the FCR to the exhaust duct. If there is a constant vortex at the height difference between the susceptor and the FCR during the process, particles can be trapped and then deposited on the surface of the periphery after the process ends. For example, particles are deposited on the inner wall of the chamber, the susceptor, the FCR, the exhaust duct or the shower head. Such particles can be stirred up when the gate valve is opened, and be deposited on the wafer.

### SUMMARY

Some examples described herein may address the above-described problems. Some examples described herein may provide a substrate processing apparatus and a substrate processing method that can reduce the contamination of a substrate.

In some examples, a substrate processing apparatus includes a chamber, a susceptor provided in the chamber, a shower head provided above the susceptor, and a flow control ring having a shape to surround the susceptor, the flow control ring having a first top surface and a second top surface that has an annular shape and is provided closer to an inner edge of the flow control ring than the first top surface at a higher level than the first top surface, the second top surface being a sloped surface whose height decreases toward the first top surface.

### BRIEF DESCRIPTION OF THE DRAWINGS

FIG. 1 is a cross-sectional view showing an example of a configuration of a substrate processing apparatus;

FIG. 2 is an enlarged view of the FCR and other components shown in FIG. 1;

FIG. 3 is a plan view of the first top surface and the second top surface of the FCR;

FIG. 4 is a diagram showing a simulation result of the gas flow;

FIG. 5 is a diagram showing a simulation result for a substrate processing apparatus according to a comparative example;

FIG. 6 is a table showing the particle occurrence in the substrate processing according to four different recipes;

FIG. 7 is a partial cross-sectional view showing another example;

FIG. 8 is a partial cross-sectional view showing another example;

FIG. 9 is a partial cross-sectional view showing another example; and

FIG. 10 is a partial cross-sectional view showing another example.

### DETAILED DESCRIPTION

A substrate processing apparatus and a substrate processing method will be described with reference to the drawings. The same or corresponding components are denoted by the same reference numerals, and redundant descriptions thereof may be omitted.

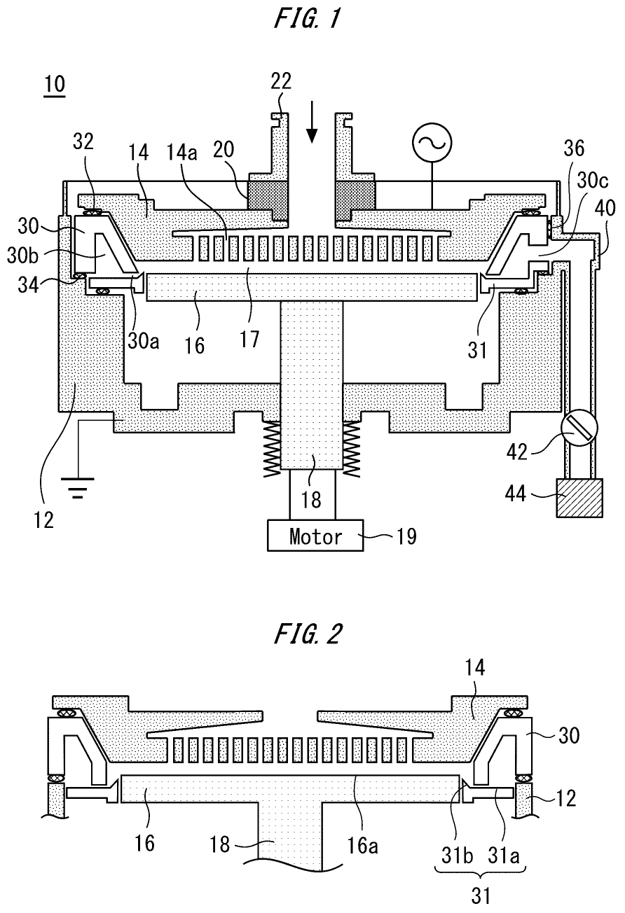

FIG. 1 is a cross-sectional view showing an example of a configuration of a substrate processing apparatus 10 according to an embodiment. In an example, the substrate processing apparatus 10 is configured as a film deposition apparatus that performs PEALD on a substrate, for example. The substrate processing apparatus 10 includes a chamber (reactor chamber) 12. In the chamber 12, a shower head 14 to which an RF power is applied is provided. A hole 14a through which gas can pass is formed in the shower head 14.

In the chamber 12, a susceptor 16 is provided to be opposed to the shower head 14. The susceptor 16 is supported by a sliding shaft 18. In an example, the sliding shaft 18 and the susceptor 16 are lifted and lowered by a motor 19. The shower head 14 and the susceptor 16 form a parallel plate structure. The thickness of a processing space 17, which is a gap between the shower head 14 and the susceptor 16, is adjusted by lifting and lowering the susceptor 16.

A gas supply part 22 is connected to the shower head 14 with an insulating component 20 disposed therebetween. The gas supply part 22 is a part for supplying a material gas to between the shower head 14 and the susceptor 16. The processing space 17 described above is a space in which a substrate placed on the susceptor 16 is subjected to film deposition or other processing.

An exhaust duct 30 is provided between the shower head 14 and the chamber 12. The exhaust duct 30 is made of ceramic, for example. An O-ring 32 appropriately compressed is provided between the exhaust duct 30 and the shower head 14. An O-ring 34 appropriately compressed is provided between the exhaust duct 30 and the chamber 12. In an example, the exhaust duct 30 is provided above a flow control ring 31 in an annular configuration in plan view.

The exhaust duct 30 is formed in an annular configuration in plan view to surround the susceptor 16. The exhaust duct 30 provides an annular flow path 30b that surrounds the processing space 17 above the susceptor 16. To guide gas from the processing space 17 to the annular flow path 30b, the flow control ring (FCR) 31 is provided. The FCR 31 is placed on the chamber 12 with an O-ring disposed therebetween, for example. The FCR 31 and the exhaust duct 30 provide a slit 30a, and the gas supplied to the processing space 17 is guided to the annular flow path 30b through the slit 30a. To discharge the gas in the annular flow path 30b to the outside, an exhaust port 30c is formed in the exhaust duct 30.

The exhaust port 30c is connected to gas exhaust part 40 provided on a side surface of the chamber 12, for example. The gas exhaust part 40 is provided to discharge the material gas used for the substrate processing. A valve 42 and a vacuum pump 44 are connected to the gas exhaust part 40. The pressure in the chamber 12 can be adjusted by adjusting the amount of the exhaust gas with the valve 42 and the vacuum pump 44.

FIG. 2 is an enlarged view of the FCR 31 and other components shown in FIG. 1. The FCR 31 includes a first top surface 31a and a second top surface 31b. In an example, the first top surface 31a is a flat surface, and the second top surface 31b is a sloped surface. The second top surface 31b is a surface at a higher level than the first top surface 31a. In the example shown in FIG. 2, the second top surface 31b is a sloped surface whose height decreases toward the first top surface 31a. In other words, the height of the second top surface 31b increases toward the susceptor 16. In the example shown in FIG. 2, the second top surface 31b is a planar surface.

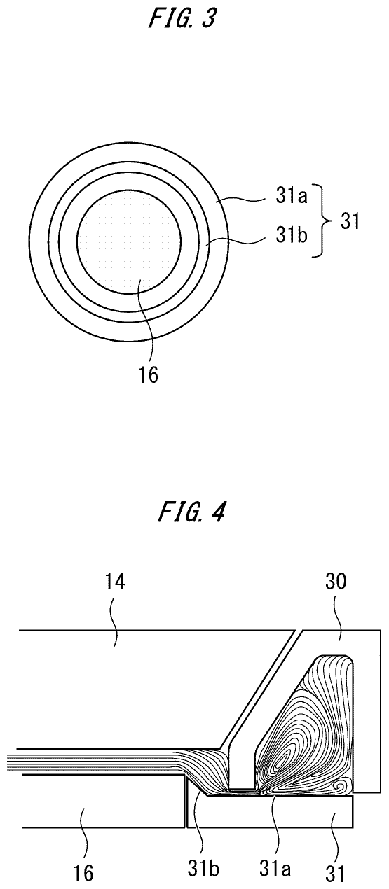

FIG. 3 is a plan view of the first top surface and the second top surface of the FCR 31. The FCR 31 surrounds the susceptor 16. The second top surface 31b is an annular surface located closer to the inner edge of the FCR 31 than the first top surface 31a.

A substrate processing method using the substrate processing apparatus described above will be described. First, the motor 19 is activated to lift or lower the susceptor 16, thereby aligning the top surface of the susceptor 16 and the highest part of the second top surface 31b of the FCR 31 with each other. In this way, the height difference between the top surface of the susceptor 16 and the top surface of the FCR 31 is eliminated or reduced.

A substrate on the susceptor 16 is then subjected to a processing by supplying a gas to the processing space 17 through the slit 14a of the shower head 14 above the susceptor and at the same time applying a high-frequency power to the shower head 14. The processing is, for example, film deposition, etching or a plasma processing for improving the quality of a film.

In the substrate processing, the gas in the processing space 17 radially flows in plan view and is guided to the exhaust duct 30 by the flow control ring 31. Since the height difference between the top surface of the susceptor 16 and the top surface of the FCR 31 is eliminated or reduced, the formation of a significant vortex is reduced in the vicinity of the boundary between the susceptor 16 and the FCR 31.

FIG. 4 is a diagram showing a simulation result of the flow of gas. As a result of the provision of the second top surface 31b, the gas above the susceptor 16 flows to above the FCR 31 without passing over a height difference. In this way, the formation of a significant vortex is reduced in the vicinity of the boundary between the susceptor 16 and the FCR 31.

FIG. 5 is a diagram showing a simulation result for a substrate processing apparatus according to a comparative example. The configuration of the FCR 31 in the comparative example differs from that of the FCR 31 of the substrate processing apparatus according to this embodiment in that there is no surface at a higher level than the first top surface 31a provided closer to the susceptor 16. In the example shown in FIG. 5, there is a surface at a lower level than the first top surface 31a between the first top surface 31a and the susceptor 16 as shown by an arrow in the drawing. Therefore, there is a height difference between the top surface of the susceptor 16 and the top surface of the FCR 31. In the substrate processing, a vortex occurs in the gas at the height difference. The vortex traps particles, which causes the contamination of the interior of the chamber. In an example, the vortex described above is likely to occur when the gap between the showerhead 14 and the susceptor 16 is less than 10.5 mm.

The simulations shown in FIGS. 4 and 5 are performed by flowing a seal gas upward at the gap between the susceptor and the FCR. The seal gas is a gas that is supplied to prevent the process gas from flowing to below the susceptor via the gap between the susceptor and the FCR. The seal gas is He, for example.

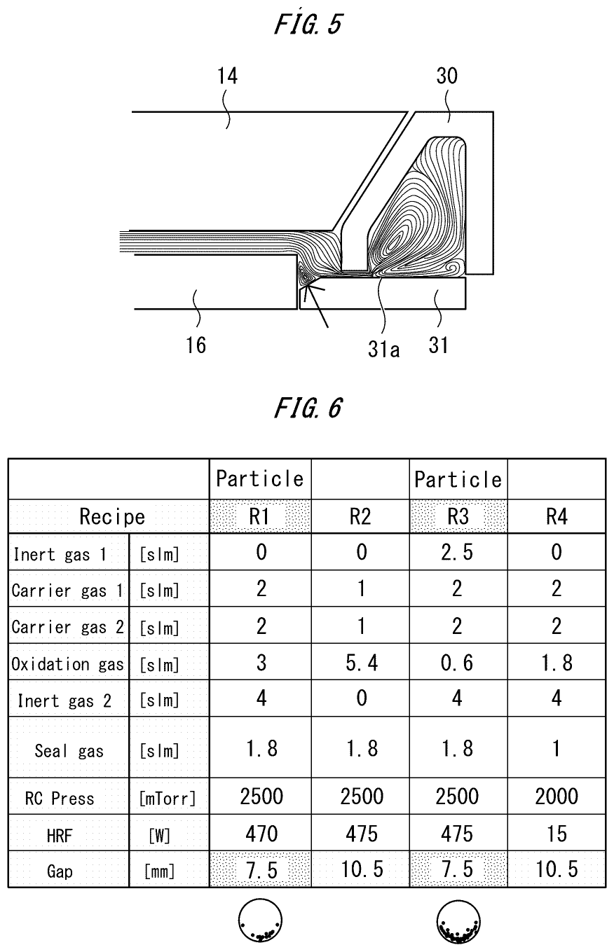

FIG. 6 is a table showing the particle occurrence in the substrate processing according to four different recipes R1 to R4. The gap between the shower head and the susceptor is as narrow as 7.5 mm in recipes R1 and R3, while the gap is as wide as 10.5 mm in recipes R2 and R4. In FIG. 6, “Particle” shown above “R1” and “R3” indicates that significant particles occur under these conditions. The particle occurrence is shown in the wafer maps shown at the bottom of FIG. 6. This experimental result shows that the problem of particles is likely to arise when the gap between the shower head and the susceptor is small. The presence or absence of significant particles depends not only on the size of the gap between the shower head and the susceptor but also on other various factors such as gas flow rate. In general, however, particles become more likely to occur as the gap decreases. However, even with such small gap, the problem can be suppressed by reducing height difference between the top surface of the susceptor 16 and the top surface of the FCR 31.

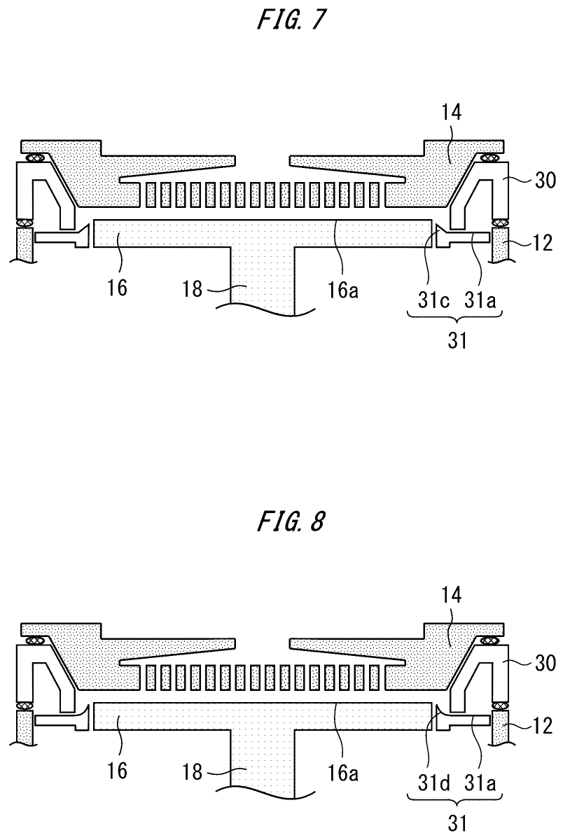

FIG. 7 is a partial cross-sectional view showing another example of the substrate processing apparatus. In this example, in the substrate processing, the height of the top surface of the susceptor 16 is not the same as the height of the highest part of the second top surface 31c. In this example, the top surface of the susceptor 16 is higher than the highest part of the second top surface 31c. However, since the FCR 31 has the second top surface 31c, the height difference between the susceptor and the FCR is smaller than when the FCR 31 does not have the second top surface 31c, so that the occurrence of a vortex in the vicinity of the gap between the susceptor and the FCR can be reduced.

FIG. 8 is a partial cross-sectional view showing another example of the substrate processing apparatus. A second top surface 31d of the FCR 31 is a curved surface. The curved surface can reduce the friction of the gas used for the substrate processing that arises when the gas flows from above the susceptor 16 to above the FCR 31. The second top surface 31d having the curved shape contributes to reducing the occurrence of a vortex.

In all the examples described above, the occurrence of a vortex between the first top surface and the second top surface of the FCR can be reduced by connecting the first top surface and the second top surface without a height difference.

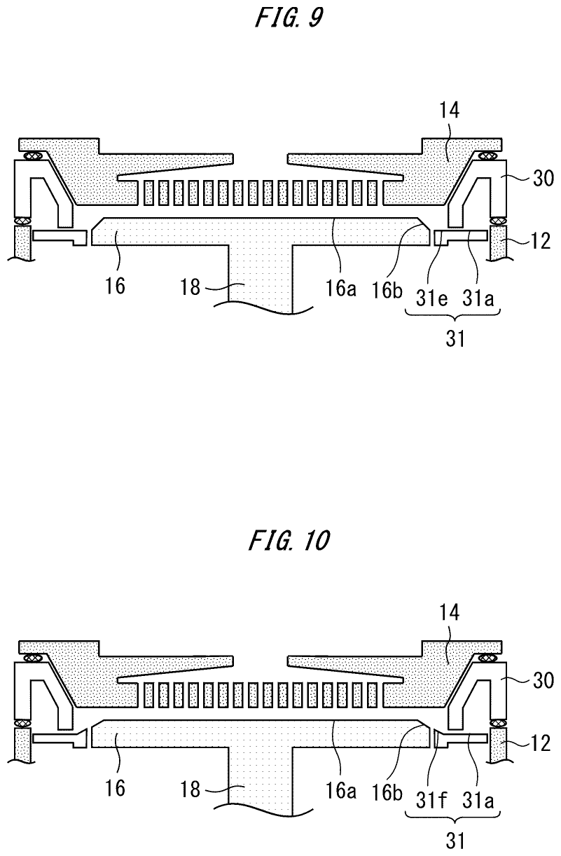

FIG. 9 is a partial cross-sectional view showing another example of the substrate processing apparatus. In this example, the top surface of the susceptor 16 includes a central top surface 16a, which forms a central part of the top surface of the susceptor 16, and a peripheral top surface 16b, which forms a peripheral part of the top surface of the susceptor 16. The peripheral top surface 16b is an annular part including the outer edge of the susceptor 16. The peripheral top surface 16b is an inclined surface whose height decreases toward the outer edge of the susceptor.

The FCR 31 has the first top surface 31a and a second top surface 31e. In this example, the height of the first top surface 31a and the height of the second top surface 31e are the same.

As shown in FIG. 9, a substrate is subjected to a processing in a state where the height of an outermost part of the peripheral top surface 16b and the height of the top surface of the FCR 31 are approximately the same. Therefore, gas flows over the susceptor 16 and the FCR 31 between which there is no height difference, so that the occurrence of a vortex in the vicinity of the gap between the susceptor 16 and the FCR 31 can be reduced.

FIG. 10 is a partial cross-sectional view showing another example of the substrate processing apparatus. In this example, the susceptor has the peripheral top surface 16b, and the FCR 31 has a second top surface 31f. The peripheral top surface 16b and the second top surface 31f are connected without a height difference, and therefore, the occurrence of a vortex in the vicinity of the gap between the susceptor 16 and the FCR 31 can be reduced.

In the examples shown in FIGS. 9 and 10, the susceptor has a sloped surface. If not only the susceptor but also the FCR has a sloped surface, the effect of reducing the occurrence of a vortex can be increased. The sloped surface of the susceptor may be a planar surface or a curved surface.

1. A substrate processing apparatus, comprising:
a chamber;
a susceptor provided in the chamber;
a shower head provided above the susceptor;
a flow control ring configured to surround the susceptor;
an annular exhaust duct; and
an annular slit formed between the flow control ring and the annular exhaust duct,
wherein the flow control ring comprises an inner edge surface and a top surface comprising a first top surface and a second top surface, wherein the second top surface, in a cross section of a vertical plane extending through a diameter of the flow control ring, comprises a sloped surface connecting the inner edge surface to the first top surface,
wherein the first top surface is a planar surface and defines a lower boundary of the slit.

2. The substrate processing apparatus of claim 1, wherein the sloped surface is a linearly sloped surface.

3. The substrate processing apparatus of claim 2, wherein a height of the second top surface decreases toward the first top surface.

4. The substrate processing apparatus of claim 3, further comprising a susceptor motor configured to move the susceptor into a first position, wherein a susceptor top surface and an uppermost portion of the second top surface are aligned.

5. The substrate processing apparatus of claim 1, wherein the first top surface is a horizontally planar surface.

6. The substrate processing apparatus of claim 1, wherein the first top surface and the second top surface are connected without a height difference.

7. The substrate processing apparatus of claim 1, wherein the exhaust duct is provided above the flow control ring in an annular configuration in plan view.

8. The substrate processing apparatus of claim 1, wherein the first top surface extends to an outer edge of the flow control ring.

9. The substrate processing apparatus of claim 1, wherein the susceptor comprises a susceptor edge surface and a susceptor top surface comprising a central top surface and an annular peripheral top surface, wherein the peripheral top surface, in a cross section of a vertical plane extending through a diameter of the susceptor, comprises a susceptor sloped surface connecting the central top surface to the susceptor edge surface.

10. The substrate processing apparatus of claim 9, wherein the susceptor sloped surface is a linearly sloped surface in a cross section of the vertical plane extending through the diameter of the susceptor.

11. The substrate processing apparatus of claim 10, wherein a height of the peripheral top surface decreases toward the susceptor edge surface.

12. The substrate processing apparatus of claim 11, further comprising a susceptor motor configured to move the susceptor into a first position, wherein an uppermost portion of the second top surface and a lowermost portion of the peripheral top surface are aligned.

13. A substrate processing apparatus, comprising:
a chamber;
a susceptor provided in the chamber;
a shower head provided above the susceptor;
a flow control ring configured to surround the susceptor;
an annular exhaust duct; and
an annular slit formed between the flow control ring and the annular exhaust duct,
wherein the susceptor comprises an edge surface and a top surface comprising of a central top surface and an annular peripheral top surface, wherein the peripheral top surface, in a cross section of a vertical plane extending through a diameter of the susceptor, comprises a sloped surface connecting the central top surface to the edge surface, and
wherein the flow control ring comprises a planar flow control ring top surface defining a lower boundary of the slit.

14. The substrate processing apparatus of claim 13, wherein the sloped surface is a linearly sloped surface.

15. The substrate processing apparatus of claim 14, wherein a height of the peripheral top surface decreases toward the edge surface.

16. The substrate processing apparatus of claim 15, further comprising a susceptor motor configured to move the susceptor into a first position, wherein the planar flow control ring top surface and a lowermost portion of the peripheral top surface are aligned.

17. The substrate processing apparatus of claim 13, wherein the planar flow control ring top surface is a horizontally planar surface.

18. The substrate processing apparatus of claim 13, wherein the central top surface and the peripheral top surface are connected without a height difference.

19. The substrate processing apparatus of claim 13, further comprising a processing space disposed below the shower head and above the susceptor, wherein the annular exhaust duct provides an annular flow path, and wherein the slit fluidly connects the processing space to the annular flow path.

20. The substrate processing apparatus of claim 13, wherein an outer edge of the flow control ring is connected to a chamber wall by an o-ring.
